(19) United States
(12) Patent Application Publication
(10) Pub. No.: US 2026/0099655 A1
(43) Pub. Date: Apr. 9, 2026

(54) DEFORMATION FOR PATH GENERATION

(71) Applicant: ABB SCHWEIZ AG, Baden (CH)

(72) Inventors: Changnian Qian, Shanghai (CN); Lei Mao, Shanghai (CN); Dongjin Kim, Shanghai (CN)

(21) Appl. No.: 19/418,050

(22) Filed: Dec. 12, 2025

Related U.S. Application Data
(63) Continuation of application No. PCT/CN2023/100189, filed on Jun. 14, 2023.

(51) Int. Cl. G06F 30/27

(52) U.S. Cl. CPC G06F 30/27

(57) ABSTRACT

Embodiments of present disclosure provide a method, a device, a computer-readable storage medium and a computer program product for deformation for path generation. The method includes deforming a three-dimensional model of a path for an object based on a mapping of the three-dimensional model and a point cloud of the object. A plurality of parameters in the deformed three-dimensional model can be adjusted based on a comparison of the three-dimensional model and the point cloud of the object. The method includes generating an updated path for the object according to the adjusted three-dimensional model.

### FIELD

Embodiments of the present disclosure generally relate to the field of computer, and in particular to a method, a device, a computer-readable storage medium and a computer program product for deformation for path generation.

### BACKGROUND

A three dimensional (3D) vision is widely used nowadays in various robot applications. One of the typical techniques is computer aided design (CAD)-model-based path generation. That is, to define paths on a CAD model and then map the paths to a point cloud taken from real parts. By a mapping operation, the paths relative to the CAD model base are transformed to the world or robot base. However, the real parts do not always have same dimensions to the CAD model, and the CAD model should be registered to the point cloud.

### SUMMARY

In general, embodiments of the present disclosure provide a solution for deformation for a path generation.

In a first aspect, it is provided a method for path generation. The method may comprise deforming a three dimensional model of a path for an object based on a mapping of the three dimensional model and a point cloud of the object, wherein the deformed three dimensional model comprises a plurality of parameters; adjusting the plurality of parameters in the deformed three dimensional model based on a comparison of the three dimensional model and the point cloud of the object; and generating a updated path for the object according to the adjusted three dimensional model.

In a second aspect, it is provided an electronic device. The device may comprise at least one processing unit; at least one memory coupled to the at least one processing unit and having instructions stored thereon, the instructions, when executed by the at least one processing unit, causing the device to perform a method according to the first aspect.

In a third aspect, it is provided a computer-readable storage medium. The computer-readable storage medium stores machine-executable instructions which, when executed by a device, may cause the device to perform a method according to the first aspect.

In a fourth aspect, it is provided a computer program product. The computer program product comprises one or more computer instructions, when the one or more computer instructions are executed by a processor, may cause the processor to perform a method according to the first aspect.

It is to be understood that the summary section is not intended to identify key or essential features of embodiments of the present disclosure, nor is it intended to be used to limit the scope of the present disclosure. Other features of the present disclosure will become easily comprehensible through the following description.

### DESCRIPTION OF DRAWINGS

Through the following detailed descriptions with reference to the accompanying drawings, the above and other objectives, features and advantages of the example embodiments disclosed herein will become more comprehensible. In the drawings, several example embodiments disclosed herein will be illustrated in an example and in a non-limiting manner, wherein:

FIG. 1 illustrates a schematic diagram of an example environment in which some embodiments of the present disclosure can be implemented;

FIG. 2A illustrates an example object on which paths can be generated according to some embodiments of the present disclosure;

FIG. 2B illustrates example point clouds of an object from different angles according to some embodiments of the present disclosure;

FIG. 2C illustrates an example difference in shape between an object and an ideal CAD model according to some embodiments of the present disclosure;

FIG. 3 illustrates a flowchart of an example method for deformation for path generation according to some other embodiments of the present disclosure;

FIG. 4A illustrates an example of original surface according to some embodiments of the present disclosure;

FIGS. 4B-4D illustrate some examples of deformations using different deformation types according to some embodiments of the present disclosure;

FIG. 5 illustrates an example process for deformation fitting according to some embodiments of the present disclosure;

FIG. 6 illustrates an example of using a pre-defined path on a deformed CAD model as a robot path according to some embodiments of the present disclosure;

FIG. 7 illustrates an example demonstration of the process for deformation fitting according to some embodiments of the present disclosure; and

FIG. 8 illustrates a block diagram illustrating an electronic device in accordance with embodiments of the present disclosure.

Throughout the drawings, the same or similar reference symbols are used to indicate the same or similar elements.

### DETAILED DESCRIPTION OF EMBODIMENTS

Principles of the present disclosure will now be described with reference to several example embodiments shown in the drawings. Though example embodiments of the present disclosure are illustrated in the drawings, it is to be understood that the embodiments are described only to facilitate those skilled in the art in better understanding and thereby achieving the present disclosure, rather than to limit the scope of the disclosure in any manner.

The term “comprises” or “includes” and its variants are to be read as open terms that mean “includes, but is not limited to.” The term “or” is to be read as “and/or” unless the context clearly indicates otherwise. The term “based on” is to be read as “based at least in part on.” The term “being operable to” is to mean a function, an action, a motion or a state can be achieved by an operation induced by a user or an external mechanism. The term “one embodiment” and “an embodiment” are to be read as “at least one embodiment.” The term “another embodiment” is to be read as “at least one other embodiment.” The terms “first,” “second,” and the like may refer to different or same objects. Other definitions, explicit and implicit, may be included below. A definition of a term is consistent throughout the description unless the context clearly indicates otherwise.

The functions or algorithms described herein may be implemented in software in one embodiment. The software may consist of computer executable instructions stored on computer readable media or computer readable storage device such as one or more non-transitory memories or other type of hardware-based storage devices, either local or networked. Further, such functions correspond to modules, which may be software, hardware, firmware or any combination thereof. Multiple functions may be performed in one or more modules as desired, and the embodiments described are merely examples. The software may be executed on a digital signal processor, ASIC, microprocessor, or other type of processor operating on a computer system, such as a personal computer, server or other computer system, turning such computer system into a specifically programmed machine.

The functionality can be configured to perform an operation using, for instance, software, hardware, firmware, or the like. For example, the phrase “configured to” can refer to a logic circuit structure of a hardware element that is to implement the associated functionality. The phrase “configured to” can also refer to a logic circuit structure of a hardware element that is to implement the coding design of associated functionality of firmware or software. The term “module” refers to a structural element that can be implemented using any suitable hardware (e.g., a processor, among others), software (e.g., an application, among others), firmware, or any combination of hardware, software, and firmware. The term, “logic” encompasses any functionality for performing a task. For instance, each operation illustrated in the flowcharts corresponds to logic for performing that operation. An operation can be performed using, software, hardware, firmware, or the like. The terms, “component,” “system,” and the like may refer to computer-related entities, hardware, and software in execution, firmware, or combination thereof. A component may be a process running on a processor, an object, an executable, a program, a function, a subroutine, a computer, or a combination of software and hardware. The term, “processor,” may refer to a hardware component, such as a processing unit of a computer system.

The terms “a” or “an,” as used herein, are defined as one or more. Also, the use of introductory phrases such as “at least one” and “one or more” in the claims should not be construed to imply that the introduction of another claim element by the indefinite articles “a” or “an” limits any particular claim containing such introduced claim element to disclosures containing only one such element, even when the same claim includes the introductory phrases “one or more” or “at least one” and indefinite articles such as “a” or “an.” The same holds true for the use of definite articles.

Furthermore, the claimed subject matter may be implemented as a method, apparatus, or article of manufacture using standard programming and engineering techniques to produce software, firmware, hardware, or any combination thereof to control a computing device to implement the disclosed subject matter. Computer-readable storage media can include, but are not limited to, magnetic storage devices, e.g., hard disk, floppy disk, magnetic strips, optical disk, compact disk (CD), digital versatile disk (DVD), smart cards, flash memory devices, among others. In contrast, computer-readable media, i.e., not storage media, may additionally include communication media such as transmission media for wireless signals and the like.

As discussed above, in scenarios such as painting, machining, dispensing and the like, a problem in robot applications is that real work piece always suffers from machining error and deformation. When the differences are not negligible, the path accuracy becomes a problem. In this case, considering only the rigid translation between CAD model and real parts point cloud may be not enough. A very common problem in robot applications is that real work piece always suffers from machining error and deformation, etc. The real parts do not always have same dimensions to the CAD model. When the differences are not negligible, the path accuracy becomes a problem. Herein, a point cloud is a set of data points in a 3D coordinate system, which may be captured by one or more 3D cameras.

Therefore, in order to at least partially address the above and other potential problems, as well as to achieve at some technical advantages, embodiments of the present disclosure provide a solution for deformation fitting. The solution performs deformation when mapping a CAD model to a point cloud. The solution uses parametric expression to model a deformation. The parametric expression has a few variables to be optimized. The variables are optimized in an optimization process. Due to the low optimization degree of freedom (DOF), the computational effort can be reduced to a lower level, yet the accuracy can be higher than the traditional non-rigid registration. The embodiments of the present disclosure will be described mainly by taking a robot for painting as the as an example. It should be understood that any other suitable use cases are also possible, such as dispensing, welding, machining applications.

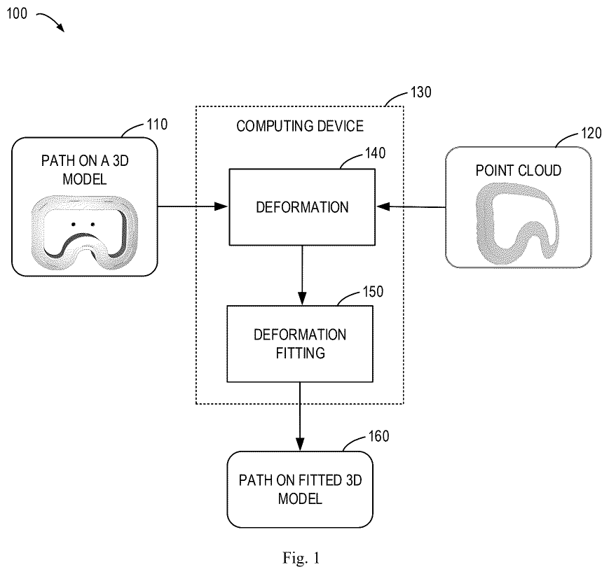

Reference is made to FIG. 1, which illustrates a schematic diagram of an example environment 100 in which some embodiments of the present disclosure can be implemented. The environment 100 is only illustrated and is not intended to suggest any limitations as to scope of use or functionality of embodiments of the disclosure described herein.

As shown in FIG. 1, the environment 100 may comprise a general-purpose computing device 130. The computing device 130 may also be a server or a cloud. The computing device 130 may obtain a 3D model (such as a CAD mode) 110. The 3D model 110 may be a path generated for a robot. The robot may perform tasks (for example, a painting job) following the path. The path information in the 3D model 110 may be considered as a ground truth.

The computing device 130 may obtain a point cloud 120. The point cloud 120 may be taken from real parts (which is referred as an object thereafter). Because the real parts do not always have same dimensions to the CAD model, the CAD-model-based path generation is very useful when the path is around small features since detecting small features by 3D vision is either hard or expensive. When the differences are not negligible, considering only the rigid translation between the CAD model and the real part point cloud is not enough.

Therefore, the computing device 130 may use deformation module 140 when mapping the CAD model to the point cloud. For example, three typical deformation formats are defined (scale, convex and bend). The deformed 3D model may be represented in a parametric expression with variables to be updated.

The deformation of the real work piece or part may be modeled by reshaping the CAD model. For example, the deformation fitting module 150 may iteratively optimize the variables to reshape the deformed 3D model so that the fitness is small enough (such as below a threshold). Finally, a fitted 3D model 160 (i.e. the reshaped path) may be read and output to the robot. The robot may use the fitted 3D model 160 as its more accuracy path for performing jobs.

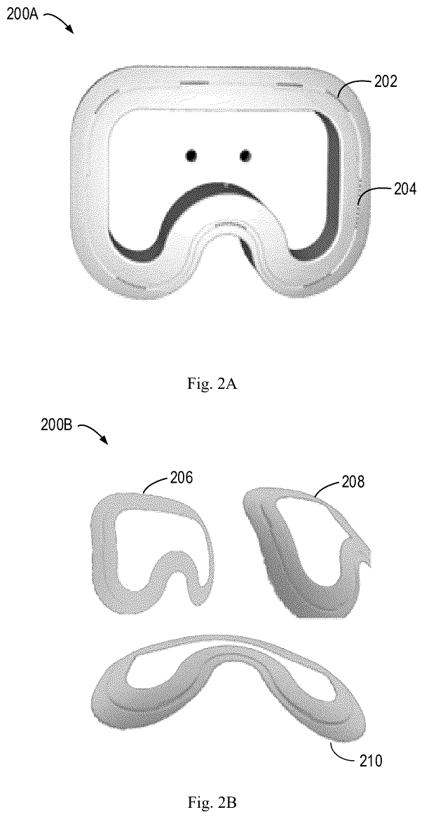

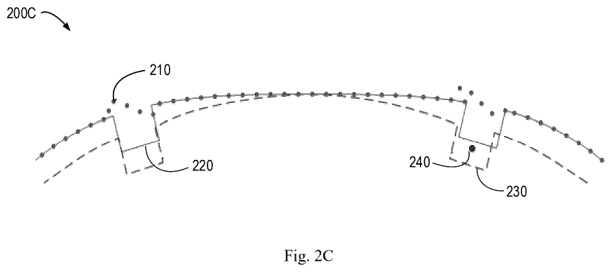

Reference is made to FIG. 2A, which illustrates an example object 200A on which paths can be generated according to some embodiments of the present disclosure. Object 200A is a work piece. Overall, the Object 200A has a flat non-linear curve surface, but somewhere it has some dents or grooves in a small scale, for example, 1 or 2 millimeters, or even less than 1 millimeter. A dent 202 and a dent 204 (dotted lines) show these small scaled dents or grooves.

Reference is made to FIG. 2B, which illustrates example point clouds 200B of an object from different angles according to some embodiments of the present disclosure. As shown in FIG. 2B, a point cloud 206, a point cloud 208 and a point cloud 210 are taken by 3D cameras form different angles of view.

The 3D cameras can capture the overall surface of the object 200A well enough, so it can be seen that a clean flat surface and these dents and grooves going downwards the surface. They there are a lot of noises when capturing the point cloud from the 3D camera's sensors. The overall shape is well captured so it's not a big issue if it requires a range of application that does not need a high accuracy. However, for tasks like painting or glue, at the edge of the object 200A, the noise is more visible and will affect finishing the tasks.

Reference is made to FIG. 2C, which illustrates an example difference 200C in shape between an object and an ideal CAD model according to some embodiments of the present disclosure. When taking the 3D model and the point cloud into a form of 2D cross sectional view at a dent, it may have an almost rectangular dent as shown in FIG. 2C.

Usually for the dent 202, a rectangular shape should be captured, but instead it's almost like a V shape. And it's not even the clean V shape because of the noise. There are a lot of the noises and especially when the scale is small, the noise tends to be more emphasized. So the noise is more profound.

Another reason is because this dent is also very small scale. When taking picture from directly above the dent 202, the noise can be suppressed much better. But usually it's hard to align the camera's position directly above the dent 202. Usually the camera is at the other angle, so when taking picture from there, a certain portion of the dent 202 is not exactly captured.

As shown in FIG. 2C, a dotted line 210 represents the point cloud. The solid line 220 represents the object 200A. The dot 240 represents the path. The dashed line 230 represents the ideal CAD model. Clearly, there is a difference between the object 200A and the ideal CAD model 230. For a high accuracy path, it has to capture exact rectangular shape of this dent. This would be a technical challenge, because it's not practical to pose the camera directly above this dent each time. Because if it is the curved surface, then it has to move the camera every time when there is a surface curve. Therefore, the line 220 may be fit to the line 230. For example, deformation may be considered when mapping the line 220 to the line 230, and parametric expression can be used to model the deformation with a few variables needed in the optimization process.

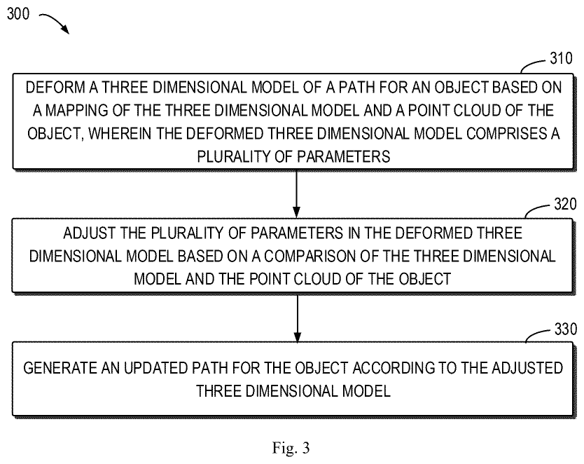

Reference is made to FIG. 3, which illustrates a flowchart of an example method 300 for deformation for path generation according to some other embodiments of the present disclosure.

At 310, the method 300 deforms a three dimensional model of a path for an object based on a mapping of the three dimensional model and a point cloud of the object. The deformed three dimensional model comprises a plurality of parameters. The plurality of parameters may comprise at least one of proportion variables, offset variables, rotation variables, translation variables and so on.

For example, the object may be a work piece as described above. The three dimensional model may be a 3D CAD model. The point cloud may be generated by a 3D camera. Because some reasons such as the noise of the point cloud, a mapping error between the point cloud and the 3D model, or an abrasion of the work piece, the 3D model and the point cloud may have a non-negligible difference.

For example, when the robot is doing a painting job in a scale of 1 mm, however, the difference is 1 cm. In this case, the path for the robot working on the work piece is not an accurate path either. Therefore, the method 300 needs to deform the 3D model of the path first and then reshape the 3D model.

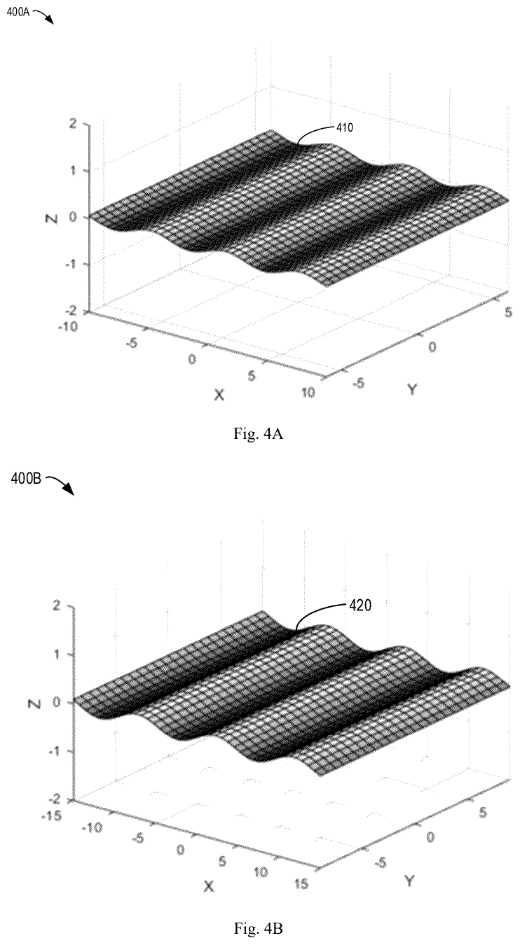

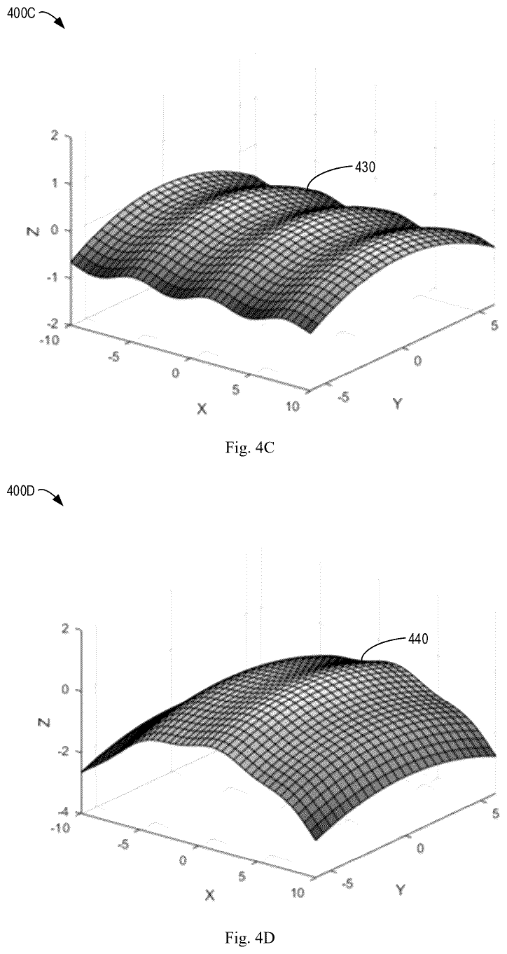

At 320, the method 300 adjusts the plurality of parameters in the deformed three dimensional model based on a comparison of the three dimensional model and the point cloud of the object. For example, using the deformation processes as described with reference to FIGS. 4A-4D.

Reference is made to FIG. 4A, which illustrates an example 400A of original surface 400A according to some embodiments of the present disclosure. The original surface 400A is a wavy surface as an example without limitation. The wavy surface has several wave troughs, such as wave trough 410.

Reference is made to FIG. 4B, which illustrates a deformation 400B using scale deformation type according to some embodiments of the present disclosure. As shown in FIG. 4B, the shape of the wave is magnified to simulate the camera looking at a tilted angle. The lens of the camera is magnifying that view. In that case, this scaled information and the scale part are defined.

An Original data set can be transferred from a scale dataset using a scale deformation. This scale dataset is the real dataset because if a person has this camera at a certain position, the person has this distorted view of the real workpiece. Then using this real data set, a mathematical framework which is defined in the matrix. It can transform from this scale deformed real data into the original surface, which is the CAD dataset representing the ideal ground truth dataset.

Deformations seen in robot applications are various but can be generally grouped in three. The first one is global deformation dominant. The second one is local deformation dominant and the third one is both. A section shape of a steel cube shall be round but sometimes it could be more like an ellipse. A plastic work piece could be bent. The above two ones are examples for global deformation. If one edge or a vertex of a steel cube is abraded, then this is an example for local deformation. For soft work pieces, e.g., shoe sole made of rubber, it could suffer from both global and local deformation.

The present discourse focuses on the cases where global deformation is dominant. When the path is around small features, the proposed method is useful since detect small features from point cloud is either hard or expensive.

To simplify the calculation, a necessary preprocessing is to move the base to the center of gravity. For example, a point of the CAD model can be expressed, for example, by:

$${p}_{i} = ( {x}_{i} , {y}_{i} , {z}_{i} ) \qquad ( 1 )$$

where i represents the number or counting of a point; x, y, z represent three axis of a 3D coordinate respectively.

The corresponding point of pᵢ in the reshaped CAD model can be expressed, for example, by:

$${p}_{i}^{cor} = g ( {p}_{i} ) \qquad ( 2 )$$

where g ( ) represents the format of the deformation;

$${p}_{i}^{cor}$$

represents the point i of the reshaped CAD model.

In the case of scaling deformation, g ( ) can be expressed, for example, by:

$$g ( {p}_{i} ) = [ \begin{matrix}{x}_{i} * {k}_{x} + {b}_{x} \\ {y}_{i} * {k}_{y} + {b}_{y} \\ {z}_{i} * {k}_{z} + {b}_{z}\end{matrix} ] \qquad ( 3 )$$

where kₓ, k_{y}, k_{z} and bₓ, b_{y}, b_{z} represent the variables to be optimized.

After the deformation operation, the CAD model may become bigger or smaller in different directions. For example, wave trough 420 becomes bigger but smoother.

Reference is made to FIG. 4C, which illustrates a deformation 400C using convex deformation type according to some embodiments of the present disclosure. In the case of convex deformation, g ( ) can be expressed, for example, by:

$$g ( {p}_{i} ) = [ \begin{matrix}{x}_{i} \\ {y}_{i} \\ {z}_{i} + {K}_{x} + {X}_{i} + {K}_{y} + {Y}_{i}\end{matrix} ] \qquad ( 4 )$$

$$where$$

$${X}_{i} = [ 1 {x}_{i} {x}_{i}^{2} {x}_{i}^{3} … {x}_{i}^{n} ]$$

$${Y}_{i} = [ {y}_{i} {y}_{i}^{2} {y}_{i}^{3} … {y}_{i}^{m} ]$$

$${K}_{x} = {[ {k}_{x \_ 0} {k}_{x \_ 1} {k}_{x \_ 2} … {k}_{x \_n} ]}^{′}$$

$${K}_{y} = {[ {k}_{y \_ 1} {k}_{y \_ 2} … {k}_{x \_m} ]}^{′}$$

Where n and m represent the powers of the polynomials, which are integers equal to or greater than zero. n and m should be determined according to the real workpiece deformation. Kₓ and K_{y} represent the variables to be optimized. In Kₓ, k_{x_n} represents Kₓ at power of n. In K_{y}, y_{x_n} represents yₓ at power of n.

FIG. 4D illustrates an example of deformation 400D using bend deformation type according to some embodiments of the present disclosure. It is to be noted that with different variable values the reshaping will be more like bend or convex. These three deformation types are basic ones, and any deviation belongs to these three deformation types can be fitted according to the polynomial formulas, or other types of formulas without limitations.

It is to be understood that these are some types of transferring from the real dataset into the original dataset. Actually, tests with different figurations of the camera's installation and also tests with many different work pieces can be done. It is proven that by using the mathematical matrix for deformation, it can correct these noises and suppress the noise and map it back to the ideal CAD model.

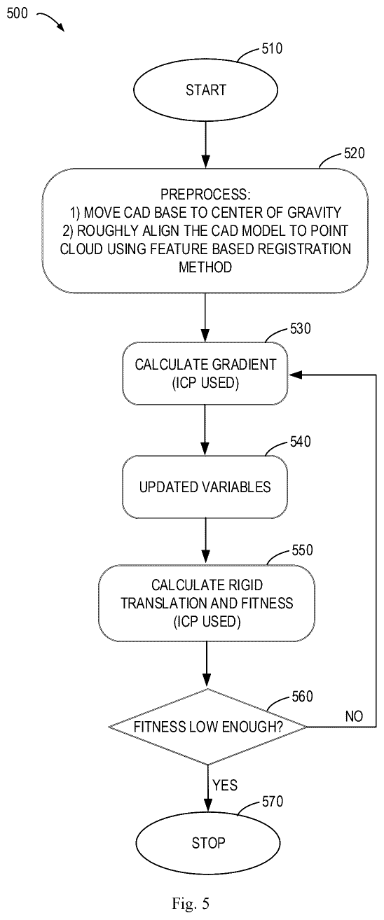

Referring back to FIG. 3, the comparison of the three dimensional model and the point cloud of the object may be done by using of an iterative gradient approach. A high level idea of the iterative gradient descent approach uses an iterative method to fit (which is also referred to as reshaping) the deformed 3D model. In each iterative step, first the deformation variables are updated, then an iterative closest point (ICP) approach is used to calculate the error function (which is referred as a fitness). To update the deformation variables, a gradient descent approach can be used. The example iterative descent approach will be discussed in detail with reference to FIG. 5.

Reference is made to FIG. 5, which illustrates an example process 500 for deformation fitting according to some embodiments of the present disclosure. At 510, the process 500 may start. At 520, a pre-process may be performed. For example, move base to the center of gravity for both the CAD model and the target point cloud. Further, the process 500 may roughly align the CAD model to the target point cloud. The result is the initial condition of the following optimization.

At 530, the process 500 may calculate gradients. Since there is no analytic expression for the error function (or the fitness), numeric method is used to estimate the gradients. For each variable kᵢ, a small deviation Δ_{k_i} can be given, and fix other variables. By running the ICP approach to get the fitness deviation Δ_{fitness_i}, and then a partial derivative as a gradient, which can be calculated, for example, by

$${∇}_{i} = {Δ}_{fitness \_ i} / {Δ}_{k \_ i} \qquad ( 5 )$$

where ∇ᵢ represents the gradient for variable kᵢ.

The process 500 may repeat the calculation for other variables and get gradients, for example, as follows:

$$∇ = {[ {∇}_{0} {∇}_{1} {∇}_{2} … ]}^{′} \qquad ( 6 )$$

where ∇ represents the gradient vector.

At 540, the process 500 may update the variables using the gradient descent approach, which can be represented, for example, by:

$${K}^{s + 1} = {K}^{s} - γ ∇ \qquad ( 7 )$$

where y represents a step size; y may also be understood as a learning rate that determines how fast it can be updated; s represents a step index; K=[k₀ k₁ k₂ . . . ] represents the optimization variable array.

At 550, the process 500 may use the updated variables to run the ICP approach for a second round, and get a new fitness. At 560, the process 500 may check if the fitness is small enough. If yes, the process 500 may return the last updated K. Otherwise, the process 500 may go back to 530.

Referring back to FIG. 3, at 330, the method 300 generates an updated path for the object according to the adjusted three dimensional model. For example, the process 500 iteratively performed for 1000 times and meets the requirement for a termination. The method 300 uses the 1000^{th} updated parameters as the fitted 3D model, and the path on the fitted 3D model may be used as an updated path for the robot to work on the work piece.

By implementing the example embodiments of FIG. 3, it can solve a common practical problem in 3D robot-vision applications and improves the accuracy for CAD based path generation. In some example embodiments, it is suitable for 3D robot vision cases where the global deformation is dominant, and the path is around small scaled features. It can also enable new robot applications which are not possible, hard, or expensive with respect to traditional technology. Due to the low optimization degree of freedom (DOF), the computational effort can be lower, yet the accuracy can be higher than the traditional non-rigid registration.

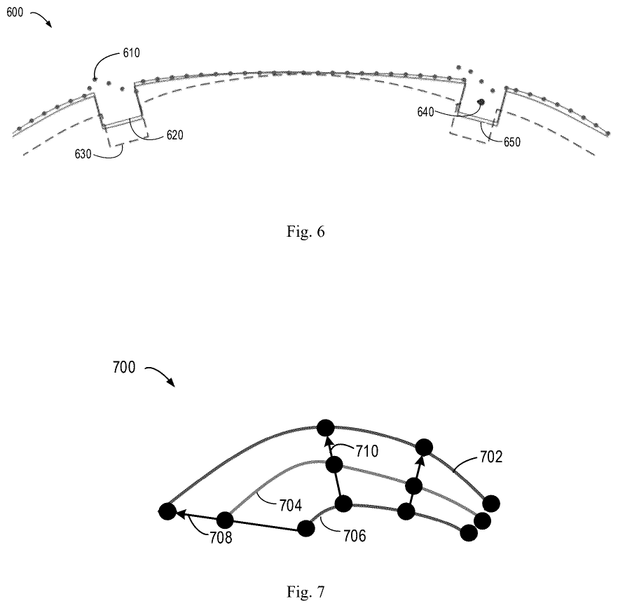

Reference is made to FIG. 6, which illustrates an example 600 of using a pre-defined path on a deformed CAD model as a robot path according to some embodiments of the present disclosure. A dotted line 610 represents the point cloud. The solid line 620 represents the object 200A. The dot 640 represents the path. The dashed line 630 represents the initial CAD model. The solid line 650 represents the reshaped CAD model.

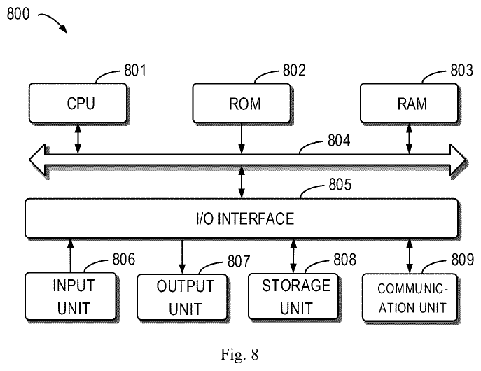

It can be seen that the difference between the object 200A and the reshaped CAD model is less than the difference between the object 200A and the initial CAD model. In order to more clearly demonstrate the technical effect of the present disclosure, FIG. 7 shows mock-up envelops of on partial part of the object.

Reference is made to FIG. 7, which illustrates an example of demonstration 700 of the process for deformation fitting according to some embodiments of the present disclosure. Envelop 702 represents the fitted CAD model. Envelop 704 represents the point cloud of the partial part of the object. Envelop 706 represents the original CAD model. The arrows (such as arrows 708 and 710) schematically show the directions that the points moved from the original CAD model to fitted CAD model.

In this case, the initial fitness is 2.081524, and after 114 steps of fitting it becomes 0.130347. The adopted defamation type is convex. It can be seen that he difference between the fitted CAD model and the point cloud is reduced compared to the difference between the original CAD model and the point cloud. Thus, the reshaped path may be read and output to the robot for a higher accuracy path.

FIG. 8 schematically illustrates a block diagram of an electronics device 800 in accordance with embodiments of the present disclosure. As indicated, the device 800 includes a central processing unit (CPU) 801, which can execute various appropriate actions and processing based on the computer program instructions stored in a read-only memory (ROM) 802 or the computer program instructions loaded into a random access memory (RAM) 803 from a storage unit 808. The RAM 803 also stores all kinds of programs and data required by operating the storage device 800. CPU 801, ROM 802 and RAM 803 are connected to each other via a bus 804, to which an input/output (I/O) interface 805 is also connected.

A plurality of components in the device 800 are connected to the I/O interface 805, comprising: an input unit 806, such as a keyboard, a mouse and the like; an output unit 807, such as various types of displays, loudspeakers and the like; a storage unit 808, such as a storage disk, an optical disk and the like; and a communication unit 809, such as a network card, a modem, a wireless communication transceiver and the like. The communication unit 809 allows the device 800 to exchange information/data with other devices through computer networks such as Internet and/or various telecommunication networks.

Each procedure and processing described above, such as the method 300, can be executed by a processing unit 801. For example, in some example embodiments, the method 300 can be implemented as computer software programs, which are tangibly included in a machine-readable medium, such as a storage unit 808. In some example embodiments, the computer program can be partially or completely loaded and/or installed to the device 800 via the ROM 802 and/or the communication unit 809. When the computer program is loaded to the RAM 803 and executed by the CPU 801, one or more steps of the above described method 300 are implemented. Alternatively, in other embodiments, the CPU 801 may also be configured in any proper manner to implement the above process/method.

The present disclosure may be a method, a device, a system and/or a computer program product. The computer program product can include a computer-readable storage medium loaded with computer-readable program instructions thereon for executing various aspects of the present disclosure.

The computer readable storage medium can be a tangible device that can retain and store instructions for use by an instruction execution device. The computer readable storage medium may be, for example, but not limited to, an electronic storage device, a magnetic storage device, an optical storage device, an electromagnetic storage device, a semiconductor storage device, or any suitable combination thereof. More specific examples (a non-exhaustive list) of the computer readable storage medium would include: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination thereof. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium, or downloaded to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembly instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some example embodiments, by means of state information of the computer readable program instructions, an electronic circuitry including, for example, programmable logic circuitry, field-programmable gate arrays (FPGA), or programmable logic arrays (PLA) can be personalized to execute the computer readable program instructions, thereby implementing various aspects of the present disclosure.

Aspects of the present disclosure are described herein with reference to flowchart and/or block diagrams of methods, apparatus (systems), and computer program products according to embodiments of the present disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which are executed via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which are executed on the computer, other programmable apparatus, or other device implement the functions/acts specified in the flowchart and/or block diagram block or blocks.

The flowchart and block diagrams illustrate the architecture, functionality, and operation of possible implementations of systems, methods and computer program products according to various embodiments of the present disclosure. In this regard, each block in the flowchart or block diagrams may represent a module, snippet, or portion of codes, which comprises one or more executable instructions for implementing the specified logical function(s). In some alternative implementations, the functions noted in the block may be implemented in an order different from those illustrated in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or by combinations of special purpose hardware and computer instructions.

The following example implementations provide a non-exhaustive set of illustrative aspects of the present discourse herein.

In a first aspect, it is provided a method for path generation. The method may comprise deforming a three dimensional model of a path for an object based on a mapping of the three dimensional model and a point cloud of the object, wherein the deformed three dimensional model comprises a plurality of parameters; adjusting the plurality of parameters in the deformed three dimensional model based on a comparison of the three dimensional model and the point cloud of the object; and generating an updated path for the object according to the adjusted three dimensional model. These example embodiments can improve the accuracy for CAD based path generation.

In some example embodiments, deforming the three dimensional model may comprise: moving a first centroid of the three dimensional model and a second centroid of the point cloud to a common base point; and aligning the three dimensional model to the point cloud based on one of a plurality of deformation types. These example embodiments can provide a fast rough alignment initially.

In some example embodiments, the plurality of deformation types may comprise scale, bend and convex. In some example embodiments, aligning the three dimensional model to the point cloud based on the one of a plurality of deformation types may comprise: selecting a deformation type from the plurality of deformation types based on respective fitness, wherein fitness related to a deformation type indicates that an error between the point cloud and the aligned three dimensional model. These example embodiments can make it suitable for the case that the path is around small scaled features.

In some example embodiments, adjusting the plurality of parameters in the deformed three dimensional model may comprise: determining a plurality of gradients associated with the deformed three dimensional model; and adjusting the plurality of parameters in the deformed three dimensional model based on the plurality of gradients.

In some example embodiments, determining the plurality of gradients associated with the deformed three dimensional model may comprise: for each of the plurality of parameters: keeping the rest of the plurality of parameters fixed; determining a fitness deviation using an iterative closest point (ICP) approach; and determining a partial derivative based on the fitness deviation and a deviation for iteration for adjusting the plurality of parameters; and determining a plurality of partial derivatives corresponding to the plurality of parameters as a gradient vector. These example embodiments can reduce the DOF and thus can reduce the computational overhead.

In some example embodiments, the method may further comprise: determining a value of an error function using the ICP approach as fitness at a current iteration based on the updated plurality of parameters; determining whether the value of the error function is above a threshold; based on a determination that the value is above the threshold, determining the gradient vector at a next iteration; and updating the plurality of parameters based on the gradient vector at the next iteration.

In some example embodiments, updating the plurality of parameters based on the gradient vector at the next iteration may comprise: updating the plurality of parameters based on a step size for each iteration or a gradient descending rate, and based on the gradient vector at the next iteration.

In some example embodiments, the method may further comprise: based on a determination that the error is below the threshold, determining a fitted three dimensional model using the last update of the plurality of parameters. In some example embodiments, the method may further comprise: outputting the adjusted three dimensional model as the updated path for navigating a robot. Thus a path of higher accuracy can be obtained according to these example embodiments.

In some example embodiments, the path may be a first path, and the method may further comprise: selecting a second path on the object, wherein the second path is different than the first path; updating a plurality of parameters for the second path iteratively until a value of the error function associated with the second path is below the threshold; and generating an updated second path for navigating the robot using the updated plurality of parameters for the second path.

In some example embodiments, the method may be performed for the second path individually and in parallel with the method performed for the first path. In some example embodiments, a plurality of paths may exist on the object, and each of the plurality of paths may be determined on the three dimensional model represented by a CAD model. These example embodiments can increase the efficiency of path generation.

In a second aspect, it is provided an electronic device. The device comprises at least one processing unit; at least one memory coupled to the at least one processing unit and having instructions stored thereon, the instructions, when executed by the at least one processing unit, causing the device to perform a method according to the first aspect.

In a third aspect, it is provided a computer-readable storage medium. The computer-readable storage medium stores machine-executable instructions which, when executed by a device, cause the device to perform a method according to the first aspect.

In a fourth aspect, it is provided a computer program product. The computer program product comprises one or more computer instructions, when the one or more computer instructions are executed by a processor, causes the processor to perform a method according to the first aspect.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A method for path generation, comprising:
deforming a three-dimensional model of a path for an object based on a mapping of the three-dimensional model and a point cloud of the object, wherein the deformed three-dimensional model comprises a plurality of parameters;
adjusting the plurality of parameters in the deformed three-dimensional model based on a comparison of the three-dimensional model and the point cloud of the object; and
generating an updated path for the object according to the adjusted three-dimensional model.

2. The method according to claim 1, wherein deforming the three-dimensional model comprises:
moving a first centroid of the three-dimensional model and a second centroid of the point cloud to a common base point; and
aligning the three-dimensional model to the point cloud based on one of a plurality of deformation types.

3. The method according to claim 2, wherein the plurality of deformation types comprise scale, bend and convex, and wherein aligning the three-dimensional model to the point cloud based on the one of a plurality of deformation types comprises:
selecting a deformation type from the plurality of deformation types based on respective fitness, wherein fitness related to a deformation type indicates that an error between the point cloud and the aligned three-dimensional model.

4. The method according to claim 1, wherein adjusting the plurality of parameters in the deformed three-dimensional model comprises:
determining a plurality of gradients associated with the deformed three-dimensional model; and
adjusting the plurality of parameters in the deformed three-dimensional model based on the plurality of gradients.

5. The method according to claim 4, wherein determining the plurality of gradients associated with the deformed three-dimensional model comprises:
for each of the plurality of parameters:
keeping the rest of the plurality of parameters fixed;
determining a fitness deviation using an iterative closest point (ICP) approach; and
determining a partial derivative based on the fitness deviation and a deviation for iteration for adjusting the plurality of parameters; and
determining a plurality of partial derivatives corresponding to the plurality of parameters as a gradient vector.

6. The method according to claim 5, further comprising:
determining a value of an error function using the ICP approach as fitness at a current iteration based on the updated plurality of parameters;
determining whether the value of the error function is above a threshold;
based on a determination that the value is above the threshold, determining the gradient vector at a next iteration; and
updating the plurality of parameters based on the gradient vector at the next iteration.

7. The method according to claim 6, wherein updating the plurality of parameters based on the gradient vector at the next iteration comprises:
updating the plurality of parameters based on a step size for each iteration or a gradient descending rate, and based on the gradient vector at the next iteration.

8. The method according to claim 6, further comprising:
based on a determination that the error is below the threshold, determining a fitted three-dimensional model using the last update of the plurality of parameters.

9. The method according to claim 8, further comprising:
outputting the adjusted three-dimensional model as the updated path for navigating a robot.

10. The method according to claim 9, wherein the path is a first path, and the method further comprises:
selecting a second path on the object, wherein the second path is different than the first path;
updating a plurality of parameters for the second path iteratively until a value of the error function associated with the second path is below the threshold; and
generating an updated second path for navigating the robot using the updated plurality of parameters for the second path.

11. The method according to claim 10, wherein the method is performed for the second path individually and in parallel with the method performed for the first path.

12. The method according to claim 1, wherein a plurality of paths exist on the object, and each of the plurality of paths is determined on the three-dimensional model represented by a computer aided design (CAD) model.

13. An electronic device, comprising:
at least one processing unit;
at least one memory coupled to the at least one processing unit and having instructions stored thereon, the instructions, when executed by the at least one processing unit, causing the device to perform the method of claim 1.

14. A computer-readable storage medium storing machine-executable instructions which, when executed by a device, cause the device to perform the method of claim 1.

15. A computer program product comprising one or more computer instructions, when the one or more computer instructions are executed by a processor, cause the processor to perform the method of claim 1.
